(19) United States
(12) Patent Application Publication
(10) Pub. No.: US 2025/0337375 A1
(43) Pub. Date: Oct. 30, 2025

(54) POWER AMPLIFIER INCLUDING MAIN SCPA, PEAK SCPA, AND SHUNT INDUCTOR

(71) Applicant: Cypress Semiconductor Corporation, San Jose, CA (US)

(72) Inventors: David SEEBACHER, Villach (AT); Edoardo BAIESI FIETTA, Padova (IT); Davide PONTON, Villach (AT); Andrea BEVILACQUA, Padova (IT)

(73) Assignee: Cypress Semiconductor Corporation, San Jose, CA (US)

(21) Appl. No.: 18/645,236

(22) Filed: Apr. 24, 2024

(51) Int. Cl. H03F 3/24

(52) U.S. Cl. CPC H03F 3/245; H03F 2200/451

(57) ABSTRACT

A power amplifier includes a main switched capacitor power amplifier (SCPA), a peak SCPA, and a shunt inductor. The main SCPA is electrically coupled to a load. The peak SCPA is in parallel with the main SCPA and electrically coupled to the load. The shunt inductor is electrically coupled between the peak SCPA and the load.

### BACKGROUND

High efficiency power amplifiers may be used to achieve low power consumption and long battery run times. One particular challenge is to enable high efficiency even at output power back-off for modulated signals, such as Orthogonal Frequency Division Multiplexing (OFDM) signals used in Wi-Fi, as well as for constant envelope signals, such as for Bluetooth Low Energy (BLE). For these and other reasons, a need exists for the present invention.

### SUMMARY

Some examples of the present disclosure relate to a power amplifier. The power amplifier includes a main Switched Capacitor Power Amplifier (SCPA), a peak SCPA, and a shunt inductor. The main SCPA is electrically coupled to a load. The peak SCPA is electrically coupled to the load. The shunt inductor is electrically coupled between the peak SCPA and the load.

Other examples of the present disclosure relate to a system. The system includes a controller, a transceiver, and an antenna circuit. The transceiver is communicatively coupled to the controller and includes a power amplifier. The antenna circuit is electrically coupled to the transceiver. The power amplifier includes a main SCPA, a peak SCPA, and a shunt inductor. The main SCPA is electrically coupled to the antenna circuit. The peak SCPA is electrically coupled to the antenna circuit. The shunt inductor is electrically coupled between the peak SCPA and the antenna circuit.

Yet other examples of the present disclosure relate to a method. The method includes receiving an input signal at a power amplifier. The method includes generating a main output signal component via a main SCPA of the power amplifier based on the input signal. The method includes generating a peak output signal component via a peak SCPA of the power amplifier based on the input signal. The method includes transforming, via a shunt inductor, the peak output signal component. The method includes generating an output signal in response to the main output signal component and the transformed peak output signal component.

### BRIEF DESCRIPTION OF THE DRAWINGS

FIG. 1 is a schematic diagram illustrating an example power amplifier.

FIGS. 2A-2C are schematic diagrams illustrating example power amplifiers including a transformation network.

FIG. 3 is a schematic diagram illustrating another example power amplifier including a transformation network and power control.

FIGS. 4A-6B are charts illustrating a comparison between a power amplifier including a transformation network versus a similarly configured power amplifier not including a transformation network.

FIG. 7A is a schematic diagram illustrating one example of a differential voltage mode power amplifier using series combining.

FIG. 7B is a schematic diagram illustrating one example of a differential voltage mode power amplifier using parallel combining.

FIG. 8 is a block diagram illustrating one example of a system including a power amplifier.

FIGS. 9A-9C are flow diagrams illustrating an example method for generating an output signal via a power amplifier.

### DETAILED DESCRIPTION

In the following detailed description, reference is made to the accompanying drawings which form a part hereof, and in which is shown by way of illustration specific examples in which the disclosure may be practiced. It is to be understood that other examples may be utilized and structural or logical changes may be made without departing from the scope of the present disclosure. The following detailed description, therefore, is not to be taken in a limiting sense, and the scope of the present disclosure is defined by the appended claims. It is to be understood that features of the various examples described herein may be combined, in part or whole, with each other, unless specifically noted otherwise.

Switched Capacitor Power Amplifiers (SCPAs) provide good linearity as well as direct digital to analog conversion without the need of a baseband Digital to Analog Converter (DAC) and mixers to generate the signal. Due to the behavior of SCPAs as voltage sources, SCPAs may be used for voltage mode Doherty implementations without the need of impedance inversion.

Conventional SCPA Doherty implementations may be implemented using symmetrically sized main and peak amplifiers, which results in an efficiency peak at 6 dB back-off. To convert the wide range of output voltages/power in Bluetooth (as well as for more complex modulation formats), a higher back-off ratio is desirable to increase the efficiency. One approach to increasing the efficiency is the use of different supply voltages for the main and peak amplifiers to create increased efficiency also for larger back-off values. The use of different supply voltages, however, adds system complexity and is highly undesirable in low cost systems such as Bluetooth.

Accordingly, disclosed herein is a transformation network in combination with a Doherty implementation that allows both SCPA operation as well as an asymmetric Doherty load modulation resulting in a peak efficiency at larger back-off.

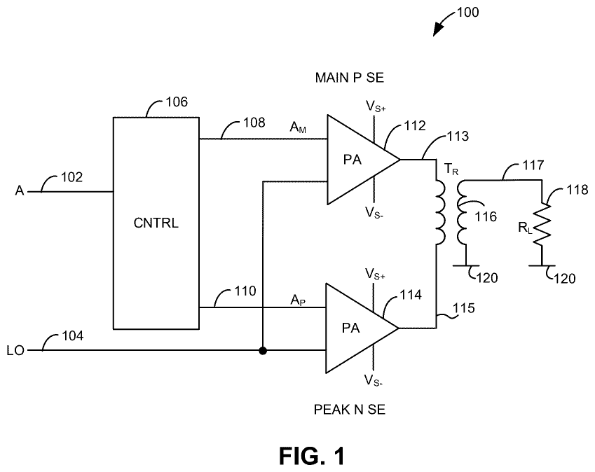

FIG. 1 is a schematic diagram illustrating one example of a power amplifier 100. Power amplifier 100 may include a voltage mode SCPA (e.g. Doherty) using single ended power amplifier stages. In some examples, power amplifier 100 is a class-D amplifier. Power amplifier 100 includes control logic (CNTRL) 106, a main SCPA 112 (i.e., MAIN P SE), a peak SCPA 114 (i.e., PEAK N SE), a transformer (T_{R}) 116 (e.g., balun), and a load resistance (R_{L}) 118. In some examples, load resistance 118 represents an antenna circuit. An input of control logic 106 receives an input signal (A) on a signal path 102. In some examples, the input signal A may include a digital signal including a digital code for controlling power amplifier 100. A first output of control logic 106 is electrically coupled to a control input of main SCPA 112 through a control signal (A_{M}) path 108. A second output of control logic 106 is electrically coupled to a control input of peak SCPA 114 through a control signal (Aₚ) path 110.

A local oscillator (LO) input of the main SCPA 112 and a LO input of the peak SCPA 114 each receive a LO signal through a LO signal path 104. The output of the main SCPA 112 is electrically coupled to a first terminal of a primary winding of transformer 116 through a signal path 113, and the output of the peak SCPA 114 is electrically coupled to a second terminal of the primary winding of transformer 116 through a signal path 115. A first terminal of a secondary winding of transformer 116 is electrically coupled to one side of load resistance 118 through a signal path 117, and a second terminal of the secondary winding of transformer 116 is electrically coupled to a common or ground node 120. The other side of load resistance 118 is electrically coupled to the common or ground node 120. Both the main SCPA 112 and the peak SCPA 114 are powered by a single supply voltage (V_{S+}/V_{S-}).

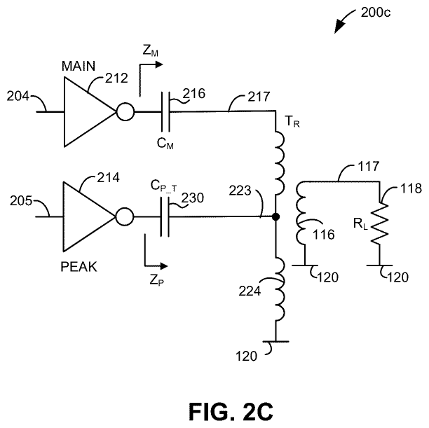

As will be further described below with reference to FIG. 3, main SCPA 112 and peak SCPA 114 may each include a plurality of cells electrically coupled in parallel. The output voltage/power of the power amplifier 100 is modified by selecting the number of active cells that are switching between the power supply and ground. The input signal A may include a digital code indicating which cells of the main SCPA 112 and the peak SCPA 114 are to be activated based on the desired output voltage/power of the power amplifier 100. Control logic 106 may decode the digital code to generate a first control signal A_{M} to activate selected cells of the main SCPA 112 and a second control signal A_{P} to activate selected cells of the peak SCPA 114. The combined output of each of the activated cells of the main SCPA 112 and the peak SCPA 114 is applied to transformer 116 and the load resistance 118.

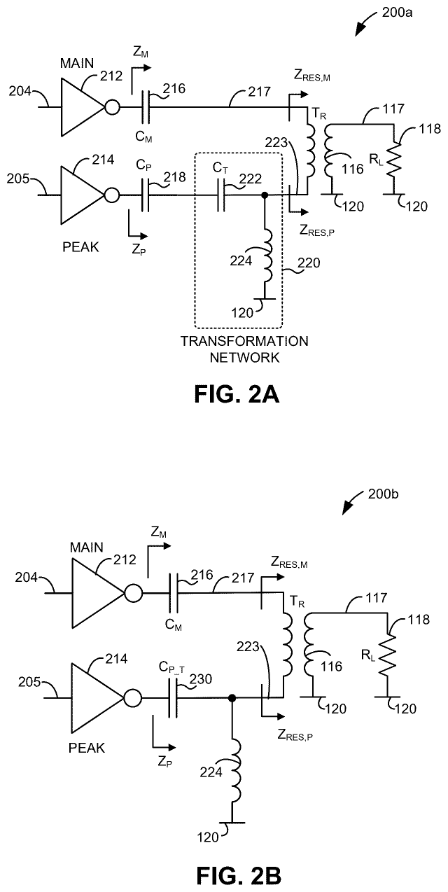

FIG. 2A is a schematic diagram illustrating an example power amplifier 200a. Power amplifier 200a may include a voltage mode SCPA (e.g. Doherty) using single ended power amplifier stages. In some examples, power amplifier 200a may provide or form a part of power amplifier 100 of FIG. 1. In some examples, power amplifier 200a is a class-D amplifier. For simplicity of the description, power amplifier 200a includes a single main SCPA cell including a first inverter 212 (i.e., MAIN) in series with a first capacitor 216 and a single peak SCPA cell including a second inverter 214 (i.e., PEAK) in series with a second capacitor 218. Power amplifier 200a also includes a transformation network 220, a transformer (T_{R}) 116, and a load resistance (R_{L}) 118. Transformation network 220 includes a network capacitor 222 and a shunt inductor 224. The first capacitor 216 may have a first capacitance C_{M}, the second capacitor 218 may have a second capacitance C_{P}, and the network capacitor 222 may have a third capacitance C_{T}. In some examples, C_{M} equals C_{P}.

An input (e.g., LO input) of the first inverter 212 and the second inverter 214 are electrically coupled to input signal paths 204 and 205, respectively. The output of first inverter 212 is electrically coupled to a first terminal of the first capacitor 216. A second terminal of the first capacitor 216 is electrically coupled to a first terminal of the primary winding of transformer 116 through a signal path 217. The output of the second inverter 214 is electrically coupled to a first terminal of the second capacitor 218. A second terminal of the second capacitor 218 is electrically coupled to a first terminal of the capacitor 222. A second terminal of the capacitor 222 is electrically coupled to a first terminal of the shunt inductor 224 and a second terminal of the primary winding of transformer 116 through a signal path 223. A second terminal of the shunt inductor 224 is electrically coupled to common or ground node 120. The secondary winding of transformer 116 is electrically coupled to the load resistance 118 as previously described with reference to FIG. 1.

Transformation network 220 transforms the load impedance Z_{RES,P} presented by the transformer 116 to a lower impedance Z_{P} presented at the output of the second inverter 214 such that Z_{RES,P} is greater than Z_{P} to enable asymmetric operation of power amplifier 200a using a single supply voltage for the first inverter 212 of the main SCPA and the second inverter 214 of the peak SCPA. By including transformation network 220, the desired power may be provided from the peak SCPA from a lower supply voltage (e.g., the same supply voltage used to power the main SCPA).

FIG. 2B is a schematic diagram illustrating another example power amplifier 200b. In some examples, power amplifier 200b is similar to power amplifier 200a of FIG. 2A, except that second capacitor 218 and network capacitor 222 of power amplifier 200a are integrated into a single second capacitor 230 in power amplifier 200b. Accordingly, capacitor 230 may have a capacitance C_{P_T} less than Cₚ and less than C_{T}. Power amplifier 200b operates similarly to power amplifier 200a.

In some examples, there may be coupling between the shunt inductor 224 and the transformer 116 as illustrated by example power amplifier 200c in FIG. 2C. In this example, shunt inductor 224 and transformer 116 may be combined into a multi-access point transformer. The winding between signal paths 217 and 223 may provide a first winding of the multi-access point transformer that has relatively strong coupling to the secondary winding. The shunt inductor 224 may provide a second winding of the multi-access point transformer that has relatively weak coupling to the secondary winding.

FIG. 3 is a schematic diagram illustrating another example power amplifier 300. Power amplifier 300 may include a voltage mode SCPA (e.g. Doherty) using single ended power amplifier stages. In some examples, power amplifier 300 may provide or form a part of power amplifier 100 of FIG. 1. Power amplifier 300 is similar to power amplifier 200b previously described and illustrated with reference to FIG. 2B, except that power amplifier 300 includes a plurality of main SCPA cells and a plurality of peak SCPA cells. Power amplifier 300 includes a main SCPA 312 (i.e., MAIN P SE), a peak SCPA 314 (i.e., PEAK N SE), a transformer 116, a load resistance 118, and a shunt inductor 224.

Main SCPA 312 includes a plurality of first cells electrically coupled in parallel. Each first cell includes a first inverter 212₀ to 212_{X} and a first capacitor 216₀ to 216_{X} electrically coupled in series with the first inverter 212₀ to 212_{X}, respectively, where “X” is any suitable number of first cells. Each first capacitor 216₀ to 216_{X} has a capacitance C_{M 0} to C_{M X}, respectively. In some examples, each capacitance C_{M 0} to C_{M X} equals the capacitance C_{M} of capacitor 216 of FIG. 2B divided by X. In other examples, the capacitances C_{M 0} to C_{M X} may be binary weighted. An enlarged view of each first inverter 212₀ to 212_{X} is illustrated on the left side of main SCPA 312 as indicated by inverter 212. Each first inverter 212 may include a high side switch and a low side switch connected to the high side switch at a drain node.

Peak SCPA 314 includes a plurality of second cells electrically coupled in parallel. Each second cell includes a second inverter 214₀ to 214_{Y} and a second capacitor 230₀ to 230_{Y} electrically coupled in series with the second inverter 214₀ to 214_{Y}, respectively, where “Y” is any suitable number of second cells. Each second capacitor 230₀ to 230_{Y} has a capacitance C_{P 0} to C_{P Y}, respectively. In some examples, each capacitance C_{P 0} to C_{P Y} equals the capacitance C_{P_T} of capacitor 230 of FIG. 2B divided by Y. In other examples, the capacitances C_{P 0} to C_{P Y} may be binary weighted. An enlarged view of each second inverter 214₀ to 214_{Y} is illustrated on the left side of peak SCPA 314 as indicated by inverter 214. Each second inverter 214 may include a high side switch and a low side switch connected to the high side switch at a drain node.

In some examples, the quantity X (e.g., a first quantity) of the first cells equals the quantity Y (e.g., a second quantity) of the second cells. In other examples, the quantity X of the first cells is different from the quantity Y of the second cells. The first quantity X and the second quantity Y may be selected to provide a desired granularity for the output voltage/power from the main SCPA 312 and the peak SCPA 314 of power amplifier 300. A capacitance C_{M 0} to C_{M X} of each first capacitor 216₀ to 216_{X} may be different than a capacitance C_{P 0} to C_{P Y} of each second capacitor 230₀ to 230_{Y}, since the network capacitor 222 of FIG. 2A is integrated into capacitors 230₀ to 230_{Y}.

Each first cell of main SCPA 312 may be enabled (e.g., activated) or disabled (e.g., shut off) via a control signal (e.g., the control signal A_{M} generated from input signal A via control logic 106 of FIG. 1), such that a selected first number of first cells 320 (e.g., including inverters 212₀ to 212₂ in the example of FIG. 3) are active and the remaining cells 322 (e.g., including inverters 212_{X-1} to 212_{X} in the example of FIG. 3) are off. Each second cell of peak SCPA 314 may be enabled (e.g., activated) or disabled (e.g., shut off) via a control signal (e.g., the control signal A_{P} generated from input signal A via control logic 106 of FIG. 1), such that a selected second number of second cells 324 (e.g., including inverters 214₀ to 214₂ in the example of FIG. 3) are active and the remaining cells 326 (e.g., including inverters 214_{Y-1} to 214_{Y} in the example of FIG. 3) are off.

Depending on the phase shift caused by the transformation network (e.g., the Cr capacitance portion of second capacitors 230₀ to 230_{Y} and shunt inductor 224), the phase of the signals on signal path 205 driving the peak SCPA 314 (and/or on signal path 204 for the main SCPA 312) may be adjusted such that the signals at the transformer 116 are 180 degrees out of phase.

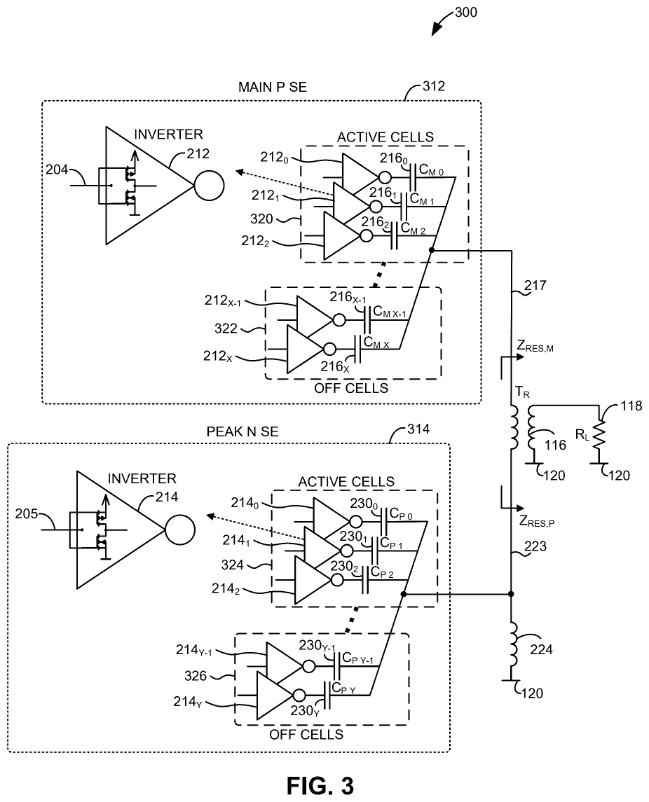

The following FIGS. 4A-6B are charts illustrating a comparison between a power amplifier including a transformation network (e.g., 220 of FIG. 2A), such as power amplifier 300 of FIG. 3, represented by FIGS. 4A, 5A, and 6A versus a power amplifier having a similar structure but not including a transformation network represented by FIGS. 4B, 5B, and 6B.

FIG. 4A illustrates a normalized control signal (CNTRL) versus a normalized output voltage (Vₙ) for a power amplifier including a transformation network. The normalized control signal CNTRL may correspond to the control signal A of FIG. 1. The normalized output voltage of the main SCPA 312 (e.g., on signal path 217) is indicated by V_{M}, the normalized output voltage of the peak SCPA 314 prior to the transformation network (e.g., at the output of each second inverter) is indicated by V_{P}, and the normalized output voltage of the peak SCPA 314 after the transformation network (e.g., on signal path 223) is indicated by V_{RES,P}. With no cells active V_{M} and V_{P} are both 0. As each first cell of the main SCPA 312 is sequentially activated, V_{M} increases linearly from 0 Vₙ to 0.3 Vₙ where all the first cells are activated. As each second cell of the peak SCPA 314 is sequentially activated, the output voltage V_{P} increases linearly from about 0.3 Vₙ to 1 Vₙ where all the second cells are also activated. The transformation network transforms V_{P} to a higher voltage to provide V_{RES,P} as each second cell of the peak SCPA 314 is sequentially activated. Thus, the peak SCPA 314 may provide a larger proportion of the output power applied to the load relative to the main SCPA 312. FIG. 4B illustrates a normalized control signal (CNTRL) versus a normalized output voltage (Vₙ) for a power amplifier not including a transformation network. As shown in FIG. 4B, V_{M} is identical to V_{M} of FIG. 4A, while V_{P} does not begin to increase until 0.5 Vₙ. In addition, without the transformation network, V_{P} is not transformed to V_{RES,P}. Therefore, without the transformation network, V_{P} would be applied to signal path 223.

FIG. 5A illustrates a normalized efficiency (DE) versus the normalized output voltage (Vₙ) for a power amplifier including a transformation network. Due to the transformation network, the efficiency is maximized between about 0.3 Vₙ and 1 Vₙ as indicated at 500. FIG. 5B illustrates the normalized efficiency (DE) versus the normalized output voltage (Vₙ) for a power amplifier not including a transformation network. Without the transformation network, the efficiency is maximized between about 0.5 Vₙ and 1 Vₙ as indicated at 502. Thus, by including a transformation network, the maximum efficiency range is increased toward a lower output voltage/power such that range 500 is greater than range 502.

FIG. 6A illustrates a normalized load (R_{L}) versus the normalized output voltage (Vₙ) for a power amplifier including a transformation network. The impedance of the main SCPA 312 (e.g., presented at the transformer 116) is indicated by Z_{M}, the impedance of the peak SCPA 314 before the transformation network (e.g., at the output of each second inverter) is indicated by Z_{P}, and the impedance of the peak SCPA 314 after the transformation network (e.g., presented at the transformer 116) is indicated by Z_{RES,P}. The transformation network transforms the impedance presented by the transformer Z_{RES,P} to a lower impedance Z_{P} enabling the peak SCPA 314 to deliver the required power from a lower supply (e.g., the same supply used for the main SCPA 312). Additionally, the impedance transformation network provides a high impedance so that the higher harmonics do not interfere with SCPA operational principles and cause capacitive switching losses. FIG. 6B illustrates the normalized load (R_{L}) versus the normalized output voltage (Vₙ) for a power amplifier not including a transformation network. Without a transformation network, the impedance Z_{M} of the main SCPA 312 decreases and the impedance Z_{P} of the peak SCPA 314 increases symmetrically as the second cells of the peak SCPA 314 are activated.

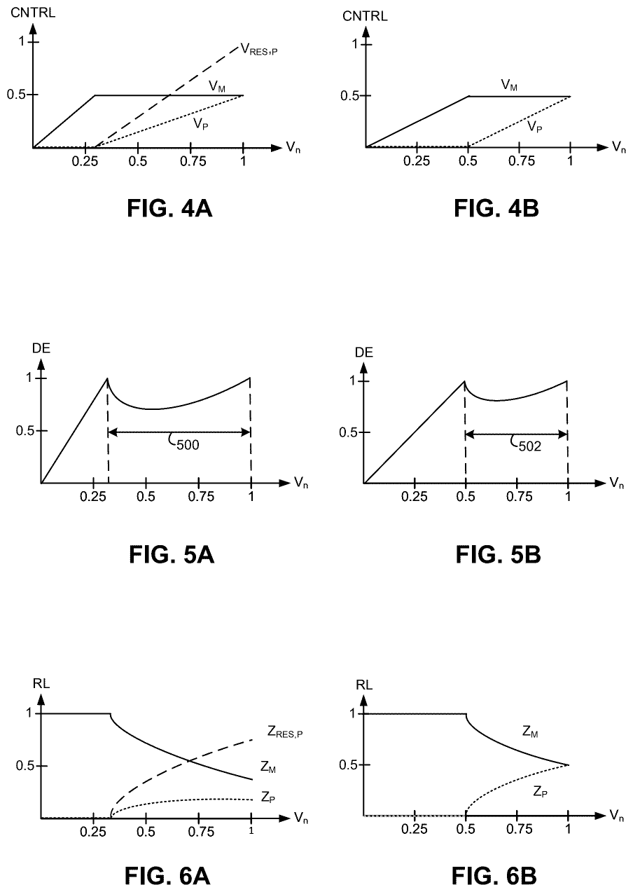

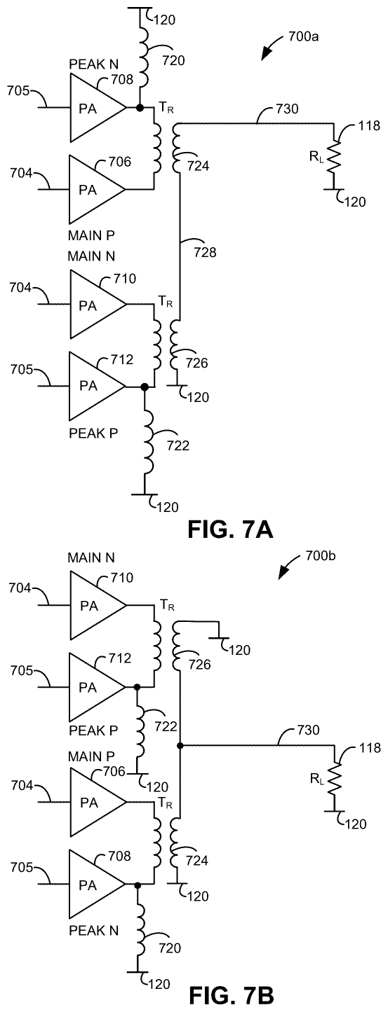

FIG. 7A is a schematic diagram illustrating another example power amplifier 700a. Power amplifier 700a may include a differential voltage mode SCPA (e.g., Doherty) using series combining. The power amplifier 700a includes a main P SCPA 706, a peak N SCPA 708, a main N SCPA 710, a peak P SCPA 712, shunt inductors 720 and 722, transformers 724 and 726, and a load resistance 118. In some examples, load resistance 118 may represent an antenna circuit. A local oscillator (LO) input of each of the main SCPAs 706 and 710 receive a LO signal through a signal path 704, and a LO input of each of the peak SCPAs 708 and 712 receive a LO signal through a signal path 705. The output of peak N SCPA 708 is electrically coupled to a first terminal of shunt inductor 720 and a first terminal of a primary winding of transformer 724. A second terminal of shunt inductor 720 is electrically coupled to a common or ground node 120. The output of main P SCPA 706 is electrically coupled to a second terminal of the primary winding of transformer 724. The output of main N SCPA 710 is electrically coupled to a first terminal of a primary winding of transformer 726. The output of peak P SCPA 712 is electrically coupled to a second terminal of the primary winding of transformer 726 and to a first terminal of shunt inductor 722. A second terminal of shunt inductor 722 is electrically coupled to the common or ground node 120. A first terminal of a secondary winding of transformer 724 is electrically coupled to one side of the load resistance 118 through a signal path 730. The other side of the load resistance 118 is electrically coupled to the common or ground node 120. A second terminal of the secondary winding of the transformer 724 is electrically coupled to a first terminal of a secondary winding of the transformer 726 through a signal path 728. A second terminal of the secondary winding of the transformer 726 is electrically coupled to common or ground node 120.

The shunt inductors 720 and 722 (as part of transformation networks) of power amplifier 700a provide the same function as shunt inductor 224 previously described with reference to power amplifier 300 of FIG. 3. The transformation networks increase the efficiency of the power amplifier 700a over a larger range of output voltages/power compared to a power amplifier not including the transformation networks.

FIG. 7B is a schematic diagram illustrating an example power amplifier 700b. Power amplifier 700b may include a differential voltage mode SCPA (e.g., Doherty) using parallel combining. The power amplifier 700b includes a main P SCPA 706, a peak N SCPA 708, a main N SCPA 710, a peak P SCPA 712, shunt inductors 720 and 722, transformers 724 and 726, and a load resistance 118. In some examples, load resistance 118 may represent an antenna circuit. A local oscillator (LO) input of each of the main SCPAs 706 and 710 receive a LO signal through a signal path 704, and a LO input of each of the peak SCPAs 708 and 712 receive a LO signal through a signal path 705. The output of peak N SCPA 708 is electrically coupled to a first terminal of shunt inductor 720 and a first terminal of a primary winding of transformer 724. A second terminal of shunt inductor 720 is electrically coupled to a common or ground node 120. The output of main P SCPA 706 is electrically coupled to a second terminal of the primary winding of transformer 724. The output of main N SCPA 710 is electrically coupled to a first terminal of a primary winding of transformer 726. The output of peak P SCPA 712 is electrically coupled to a second terminal of the primary winding of transformer 726 and to a first terminal of shunt inductor 722. A second terminal of shunt inductor 722 is electrically coupled to the common or ground node 120. A first terminal of a secondary winding of transformer 724 is electrically coupled to one side of load resistance 118 and a first terminal of the secondary winding of transformer 726 through a signal path 730. The other side of the load resistance 118 is electrically coupled to the common or ground node 120. A second terminal of the secondary winding of the transformer 724 is electrically coupled to the common or ground node 120. A second terminal of the secondary winding of the transformer 726 is electrically coupled to the common or ground node 120.

The shunt inductors 720 and 722 (as part of transformation networks) of power amplifier 700b provide the same function as shunt inductor 224 previously described with reference to power amplifier 300 of FIG. 3. The transformation networks increase the efficiency of the power amplifier 700b over a larger range of output voltages/power compared to a power amplifier not including the transformation networks.

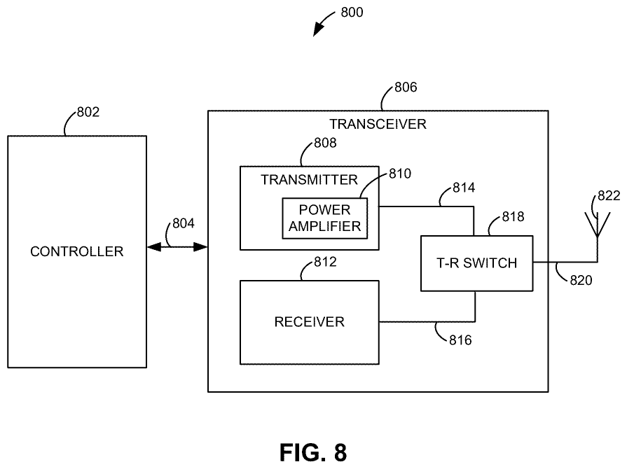

FIG. 8 is a block diagram illustrating one example of a system 800. System 800 may include a controller 802 and a transceiver 806. Controller 802 is communicatively coupled to transceiver 806 through a communication path 804. Transceiver 806 may include a transmitter 808, a receiver 812, a transmit-receive (T-R) switch 818, and an antenna 822. In some examples, transmitter 808 may include a power amplifier 810, such as power amplifier 200a, 200b, 300, 700a, or 700b as previously described and illustrated with reference to FIGS. 2A-7B to achieve low power consumption by enabling high efficiency even at output power back-off. Transmitter 808 is electrically coupled to T-R switch 818 through a signal path 814. Receiver 812 is electrically coupled to T-R switch 818 through a signal path 816. T-R switch 818 is electrically coupled to antenna 822 through a signal path 820.

Controller 802 may include a Central Processing Unit (CPU), a microprocessor, a microcontroller, an Application Specific Integrated Circuit (ASIC), a Field-Programmable Gate Array (FPGA), or other suitable logic circuitry for controlling the operation of transceiver 806. In some examples, transceiver 806 may include a Wi-Fi or Bluetooth transceiver. Transmitter 808 is configured to transmit signals provided by controller 802 via antenna 822, and receiver 812 is configured to receive signals via antenna 822 and pass the received signals to controller 802. T-R switch 818 connects transmitter 808 to antenna 822 to transmit signals via antenna 822 and connects receiver 812 to antenna 822 to receive signals via antenna 822.

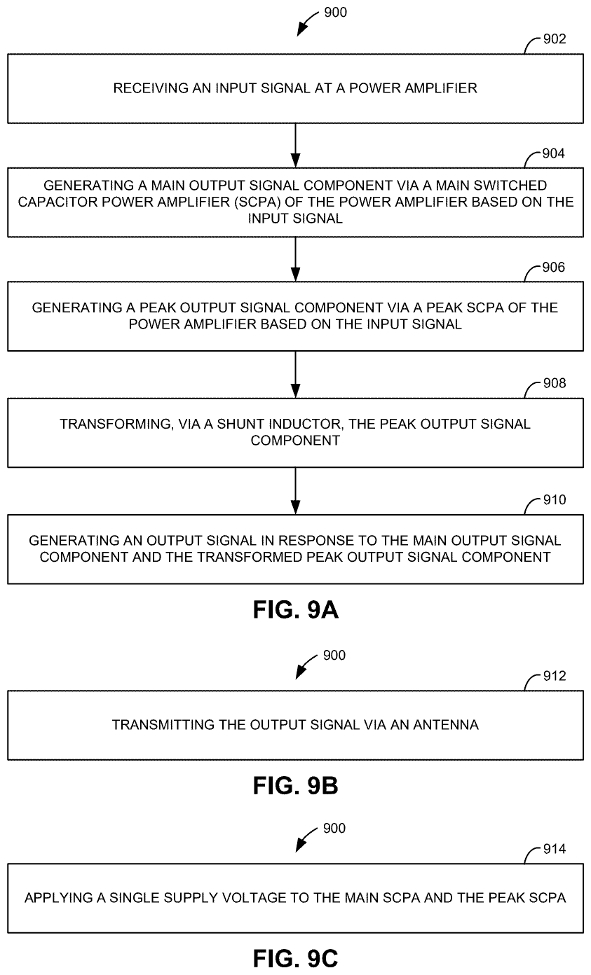

FIGS. 9A-9C are flow diagrams illustrating an example method 900 for generating an output signal via a power amplifier, such as power amplifier 200a, 200b, 300, 700a, or 700b as previously described and illustrated with reference to FIGS. 2A-7B. As illustrated in FIG. 9A at 902, method 900 includes receiving an input signal (e.g., input signal A on signal path 102 of FIG. 1) at a power amplifier. At 904, method 900 includes generating a main output signal component via a main switched capacitor power amplifier (SCPA) (e.g., 312 of FIG. 3) of the power amplifier based on the input signal. At 906, method 900 includes generating a peak output signal component via a peak SCPA (e.g., 314 of FIG. 3) of the power amplifier based on the input signal. In some examples, generating the main output signal component via the main SCPA includes selecting a first number of active first cells (e.g., 320 of FIG. 3) of the plurality of first cells based on a selected power for the output signal, and generating the peak output signal component via the peak SCPA includes selecting a second number of active second cells (e.g., 324 of FIG. 3) of the plurality of second cells based on the selected power for the output signal.

At 908, method 900 includes transforming, via a shunt inductor (e.g., 224 of FIG. 3), the peak output signal component. In some examples, transforming the peak output signal component includes transforming a higher impedance (e.g., Z_{RES,P}) at a load (e.g., at transformer 116 of FIG. 3) connected to the peak SCPA to a lower impedance (e.g., Z_{P}) at an output of each second inverter. At 910, method 900 includes generating an output signal in response to the main output signal component (e.g., on signal path 217 of FIG. 3) and the transformed peak output signal component (e.g., on signal path 223 of FIG. 3).

As illustrated in FIG. 9B at 912, method 900 may further include transmitting the output signal via an antenna (e.g., 822 of FIG. 8). As illustrated in FIG. 9C at 914, method 900 may further include applying a single supply voltage (e.g., V_{S+}/V_{S-} of FIG. 1) to the main SCPA and the peak SCPA.

It is to be understood that the features of the various exemplary embodiments described herein may be combined with each other, unless specifically noted otherwise.

Although specific examples have been illustrated and described herein, a variety of alternate and/or equivalent implementations may be substituted for the specific examples shown and described without departing from the scope of the present disclosure. This application is intended to cover any adaptations or variations of the specific examples discussed herein. Therefore, it is intended that this disclosure be limited only by the claims and the equivalents thereof.

What is claimed is:

1. A power amplifier comprising:
a main switched capacitor power amplifier (SCPA) electrically coupled to a load;
a peak SCPA electrically coupled to the load; and
a shunt inductor electrically coupled between the peak SCPA and the load.

2. The power amplifier of claim 1, further comprising:
a series capacitor electrically coupled between the peak SCPA and the shunt inductor.

3. The power amplifier of claim 1, wherein the load comprises a transformer electrically coupled to a load resistance.

4. The power amplifier of claim 1, wherein the main SCPA comprises a plurality of first cells electrically coupled in parallel, each first cell comprising:
a first inverter; and
a first capacitor electrically coupled in series with the first inverter;
wherein the peak SCPA comprises a plurality of second cells electrically coupled in parallel, each second cell comprising:
a second inverter, and
a second capacitor electrically coupled in series with the second inverter;
wherein a capacitance of each second capacitor is different than a capacitance of each first capacitor.

5. The power amplifier of claim 4, wherein a first quantity of the plurality of first cells is different from a second quantity of the plurality of second cells.

6. The power amplifier of claim 4, wherein the power amplifier is configured to generate an output signal with an output power according to a first number of active first cells of the plurality of first cells and a second number of active second cells of the plurality of second cells.

7. The power amplifier of claim 1, wherein the main SCPA and the peak SCPA are powered via a single supply voltage.

8. A system comprising:
a controller;
a transceiver communicatively coupled to the controller, the transceiver comprising a power amplifier; and
an antenna circuit electrically coupled to the transceiver,
wherein the power amplifier comprises:
a main switched capacitor power amplifier (SCPA) electrically coupled to the antenna circuit;
a peak SCPA electrically coupled to the antenna circuit; and
a shunt inductor electrically coupled between the peak SCPA and the antenna circuit.

9. The system of claim 8, wherein the power amplifier further comprises:
a series capacitor electrically coupled between the peak SCPA and the shunt inductor.

10. The system of claim 8, wherein the main SCPA comprises a plurality of first cells electrically coupled in parallel, each first cell comprising:
a first inverter; and
a first capacitor electrically coupled in series with the first inverter;
wherein the peak SCPA comprises a plurality of second cells electrically coupled in parallel, each second cell comprising:
a second inverter, and
a second capacitor electrically coupled in series with the second inverter;
wherein a capacitance of each second capacitor is different than a capacitance of each first capacitor.

11. The system of claim 10, wherein the shunt inductor is configured to reduce a voltage swing at an output of each second inverter of the plurality of second cells compared to a voltage swing on a node between the shunt inductor and the antenna circuit.

12. The system of claim 10, wherein the shunt inductor is configured to reduce an impedance at an output of each second inverter of the plurality of second cells compared to an impedance at a node between the shunt inductor and the antenna circuit.

13. The system of claim 8, wherein the power amplifier comprises a class-D amplifier.

14. The system of claim 8, wherein the transceiver comprises a Bluetooth or Wi-Fi transceiver.

15. A method comprising:
receiving an input signal at a power amplifier;
generating a main output signal component via a main switched capacitor power amplifier (SCPA) of the power amplifier based on the input signal;
generating a peak output signal component via a peak SCPA of the power amplifier based on the input signal;
transforming, via a shunt inductor, the peak output signal component; and
generating an output signal in response to the main output signal component and the transformed peak output signal component.

16. The method of claim 15, further comprising:
transmitting the output signal via an antenna.

17. The method of claim 15, further comprising:
applying a single supply voltage to the main SCPA and the peak SCPA.

18. The method of claim 15, wherein the main SCPA comprises a plurality of first cells electrically coupled in parallel, each first cell comprising:
a first inverter; and
a first capacitor electrically coupled in series with the first inverter;
wherein the peak SCPA comprises a plurality of second cells electrically coupled in parallel, each second cell comprising:
a second inverter, and
a second capacitor electrically coupled in series with the second inverter;
wherein a capacitance of each second capacitor is different than a capacitance of each first capacitor.

19. The method of claim 18, wherein generating the main output signal component via the main SCPA comprises selecting a first number of active first cells of the plurality of first cells based on a selected power for the output signal, and
wherein generating the peak output signal component via the peak SCPA comprises selecting a second number of active second cells of the plurality of second cells based on the selected power for the output signal.

20. The method of claim 18, wherein transforming the peak output signal component comprises transforming a higher impedance at a load connected to the peak SCPA to a lower impedance at an output of each second inverter.
